(19) United States
(12) Patent Application Publication
(10) Pub. No.: US 2009/0320746 A1
(43) Pub. Date: Dec. 31, 2009

(54) METHOD FOR PRODUCING GROUP III-V COMPOUND SEMICONDUCTOR

(75) Inventors: Yoshihiko Tsuchida, Ibaraki (JP); Masahiko Hata, Ibaraki (JP)

Correspondence Address: FITCH, EVEN, TABIN & FLANNERY, P. O. BOX 18415, WASHINGTON, DC, 20036, US

(73) Assignee: SUMITOMO CHEMICAL COMPANY, LIMITED, TOKYO (JP)

(21) Appl. No.: 12/524,519

(22) PCT Filed: Jan. 24, 2008
(86) PCT No.: PCT/JP2008/051465

§ 371 Date: Jul. 24, 2009

(30) Foreign Application Priority Data
Jan. 31, 2007 (JP) 2007-021297

(51) Int. Cl. C30B 25/02; C23C 16/54

(52) U.S. Cl. 117/84; 118/724

(57) ABSTRACT

The present invention provides a method for producing a Group III-V compound semiconductor, comprising a step of feeding a Group III raw material, a Group V raw material, a carrier gas, and if necessary, other raw materials, to a reactor to grow a Group III-V compound semiconductor on a substrate in the reactor by a metalorganic vapor phase epitaxy, wherein the Group III raw material and the Group V raw material are independently fed to the reactor, and hydrogen halide is fed to the reactor together with a raw material other than the Group V raw material, or the carrier gas.

### TECHNICAL FIELD

The present invention relates to a method for producing a Group III-V compound semiconductor and a reactor for metalorganic vapor phase growth used in the method.

### BACKGROUND ART

A method for epitaxially growing a desired single crystal thin film layer of nitride semiconductor continuously on a substrate by thermal decomposition of an organic metal, that is, a metalorganic vapor phase epitaxy (hereinafter referred to as “MOVPE”), is conventionally used widely to obtain a compound semiconductor, such as a nitride semiconductor, used in the production of a Group III-V compound semiconductor apparatus.

In recent years, various methods are proposed as a method for epitaxially growing a nitride semiconductor at high growth rate. For example, a hydride vapor phase epitaxy (hereinafter referred to as “HVPE”) is proposed (JP 2000-12900A, JP 2000-22212A and JP 2003-178984A). Furthermore, a metalorgnic chloride method (hereinafter referred to as “MO chloride method”) in which an organic metal for Ga source is chlorinated, and the resulting product is subjected to a reaction with ammonia to grow a nitride semiconductor is proposed. In those methods, a reactor must have a hot wall structure.

A method for growing a nitride semiconductor at high growth rate in MOVPE reactor by using cold wall is noted to mass-produce Group III-V compound semiconductor apparatus of high quality. For example, a method for producing LED on a GaN substrate having high heat dissipation property by growing an n-type GaN underlayer having a film thickness of several tens of μm or more on a sapphire substrate in an HVPE reactor, growing a light-emitting layer (quantum well structure) or a hole transport layer in an MOVPE reactor, and separating the sapphire substrate with laser is proposed as such a method (WO2005/112080A1).

However, when an n-type nitride semiconductor as an underlayer is grown in an HVPE reactor, and a light-emitting layer and a functional layer such as a hole transport layer are then grown in an MOVPE reactor, it is necessary that after growing the n-type semiconductor in the HVPE reactor and cooling the same, and the n-type semiconductor is taken out of the HVPE reactor, and is placed in another MOVPE reactor, followed by heating to increase the temperature, thereby growing a functional layer. Despite that the semiconductor can grow at high growth rate (about 100 μm/hr) in the HVPE reactor, tact time has greatly been impaired.

In the case of growing an n-type semiconductor layer and a functional layer by the conventional MOVPE, the growth rate is about 5 μm/hr, and for example, about 4 hours are required to grow a layer having a film thickness of 20 μm. On the other hand, increasing the growth rate gives rise to the problem that Ga metal separates out in a droplet shape on a GaN crystal surface.

### DISCLOSURE OF THE INVENTION

One object of the present invention is to provide a method for producing a Group III-V compound semiconductor that solves the above problems.

Another object of the present invention is to provide a reactor for metalorganic vapor phase growth that is used for the growth of a Group III-V compound semiconductor by cold wall at high growth rate with good efficiency.

As a result of earnest investigations, the present inventors have attained completion of the present invention.

That is, the present invention provides the following (1) to (4).

(1) A method for producing a Group III-V compound semiconductor, comprising a step of feeding a Group III raw material, a Group V raw material, a carrier gas, and if necessary, other raw materials, to a reactor to grow a Group III-V compound semiconductor on a substrate in the reactor by a metalorganic vapor phase epitaxy, wherein the Group III raw material and the Group V raw material are independently fed to the reactor, and hydrogen halide is fed to the reactor together with a raw material other than the Group V raw material, or the carrier gas.

(2) The method described in (1), wherein the Group V element is ammonia.

(3) The method described in (1) or (2), wherein the hydrogen halide is hydrogen chloride.

(4) A reactor for metalorganic vapor phase growth comprising an inlet for feeding raw materials, a susceptor for placing a substrate for growth thereon, and a water-cooling apparatus for cooling raw materials, wherein the reactor has a cold wall type structure, and the water-cooling apparatus is provided at the upstream side of the susceptor.

(5) The reactor described in (4), wherein the water-cooling apparatus is provided between the inlet and the susceptor.

### BRIEF DESCRIPTION OF THE DRAWINGS

FIG. 1 shows an outline of a semiconductor production apparatus.

FIG. 2 shows the relationship between a growth rate (μm/H) of a GaN layer and an HCl feed rate (sccm).

FIG. 3 shows the relationship between an X ray full width at half maximum of (0004) of a GaN layer and an HCl feed rate (sccm)

### DESCRIPTION OF REFERENCE NUMERALS AND SIGNS

1 Semiconductor production apparatus
2 Reaction apparatus (reactor for vapor phase growth)
3 Apparatus for feeding raw material
21 Main body
21A One end
22 Susceptor
31 First feed passage
32 Second feed passage
33 Third feed passage
34 Fourth feed passage
31A to 34A Discharge ports
S Substrate
G1 Carrier gas
G2 Group II raw material
G3 Group III raw material
G4 Group V raw material

### BEST MODE FOR CARRYING OUT THE INVENTION

The method for producing a Group III-V compound semiconductor of the present invention comprises a step of feeding a Group III raw material, a Group V raw material, a carrier gas, and if necessary, other raw materials, to a reactor to grow a Group III-V compound semiconductor on a substrate in the reactor by a metalorganic vapor phase epitaxy.

In this method, the Group III raw material and the Group V raw material are independently fed to the reactor.

Furthermore, hydrogen halide is fed to the reactor together with raw materials other than the Group V raw material, or the carrier gas.

Examples of the Group III raw material include trialkyl gallium represented by the formula R₁R₂R₃Ga (wherein R₁, R₂ and R₃ represent a lower alkyl group) such as trimethyl gallium ((CH₃)₃Ga, hereinafter referred to as “TMG”) and triethyl gallium ((C₂H₅)₃Ga, hereinafter referred to as “TEG”); trialkyl aluminum represented by the formula R₁R₂R₃Al (wherein R₁, R₂ and R₃ represent a lower alkyl group) such as trimethyl aluminum ((CH₃)₃Al, hereinafter referred to as “TMA”), triethyl aluminum ((C₂H₅)₃Al, hereinafter referred to as “TEA”) and triisobutyl aluminum ((i-C₄H₉)₃Al); trimethylamine alane ((CH₃)₃N:AlH₃); trialkyl indium represented by the formula R₁R₂R₃In (wherein R₁, R₂ and R₃ represent a lower alkyl group) such as trimethyl indium ((CH₃)₃In, hereinafter referred to as “TMI”) and triethyl indium ((C₂H₅)₃In); a compound in which one or two alkyl group(s) in trialkyl indium is/are substituted with halogen atom(s), such as diethyl indium chloride (C₂H₅)₂InCl); and indium halide represented by the formula InX (wherein X represents a halogen atom) such as indium chloride (InCl). Those compounds may be used alone or as mixtures thereof. Of the Group III raw material, TMG is preferred as a gallium source, TMA is preferred as an aluminum source, and TMI is preferred as an indium source.

Examples of the Group V raw material include ammonia, hydrazine, methylhydrazine, 1,1-dimethylhydrazine, 1,2-dimethylhydrazine, t-butylamine and ethylenediamine. Those compounds may be used alone or as mixtures thereof. Among the Group V raw materials, ammonia and hydrazine are preferred, and ammonia is more preferred.

Other raw materials include raw materials of n-type dopant and p-type dopant. Examples of the raw material used as the n-type dopant include silane, disilane, germane and tetramethyl germanium. Examples of the p-type dopant include Mg, Zn, Cd, Ca and Be, preferably Mg and Ca. Examples of the Mg raw material used as the p-type dopant include biscyclopentadienyl magnesium ((C₅H₅)₂Mg), bismethylcyclopentadienyl magnesium ((C₅H₄CH₃)₂Mg) and bisethylcyclopentadienyl magnesium ((C₅H₄C₂H₅)₂Mg). Examples of the Ca raw material include biscyclopentadienyl calcium ((C₅H₅)₂Ca) and its derivative, such as bismethylcyclopentadienyl calcium ((C₅H₄CH₃)₂Ca), bisethylcyclopentadienyl calcium ((C₅H₄C₂H₅)₂Ca) and bisperfluorocyclopentadienyl calcium ((C₅F₅)₂Ca); di-1-naphthalenyl calcium and its derivative; and calcium acetylide and its derivative, such as bis(4,4-difluoro-3-buten-1-ynyl) -calcium and bisphenylethyl calcium. Those compounds may be used alone or as mixtures thereof.

The Group III raw material, the Group V raw material and other raw materials are generally fed in a form of a gas.

Examples of the hydrogen halide include hydrogen chloride and hydrogen bromide, and hydrogen chloride is preferred. The amount of the hydrogen halide gas is generally about 1 cc or more, and preferably about 2 cc or more, and is generally about 50 cc or less, and preferably about 20 cc or less, per 1 mmol of the amount of the Group III raw material. The amount (volume) is based on standard state.

Examples of the carrier gas include nitrogen, hydrogen, argon and helium, and hydrogen is preferred. Those gases may be used alone or as mixtures of those.

The growth is conducted under the ordinary conditions. For example, the growth is conducted at a growth temperature of about 1,000° C. to about 1,300° C., and preferably about 1,100° C. to about 1,200° C.

The embodiment of the present invention is described by referring to the drawings.

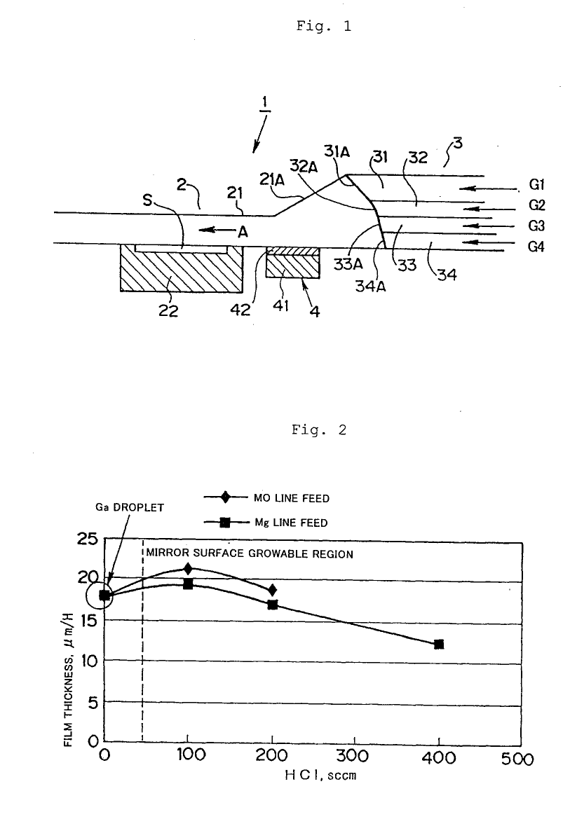

FIG. 1 shows an outline of a semiconductor production apparatus 1 used in the production method of the present invention.

The semiconductor production apparatus 1 produces, for example, a GaN-based Group III-V compound semiconductor wafer such as InGaAlN or a GaAs-based Group III-V compound semiconductor wafer.

The semiconductor production apparatus 1 comprises a reaction apparatus (reactor for vapor phase growth) 2 and a raw material feed apparatus 3 for separately feeding the raw materials and the like to the reaction apparatus 2.

The reaction apparatus 2 comprises a main body 21 comprising a quartz pipe or the like, and a susceptor 22 for setting a substrate S to the main body 21. The reaction apparatus 2 has a cold wall type structure such that the susceptor 22 is heated by a heating apparatus (not shown) such as a high frequency induction heating coil or an infrared lamp provided in the vicinity of the susceptor 22, and thereby the substrate S set to the susceptor 22 can be heated to a required temperature.

The reaction apparatus 2 is a vertical reactor form, and has, for example, a constitution that one 2-inch substrate can be set. The reaction apparatus 2 is not limited to the vertical reactor form, and may be other forms.

The raw material feed apparatus 3 feeds the necessary raw materials and a carrier gas to the reaction apparatus 2 to grow a single crystal thin film layer of a Group III-V compound semiconductor on the substrate S in the reaction apparatus 2 by MOCVD method.

The raw material feed apparatus 3 comprises a first feed passage 31 for feeding a carrier gas to the reaction apparatus 2, a second feed passage 32 for feeding a Group II raw material to the reaction apparatus 2, a third feed passage 33 for feeding a Group III raw material to the reaction apparatus 2, and a fourth feed passage 34 for feeding a Group V raw material to the reaction apparatus 2. A carrier gas G1, a Group II raw material G2, a Group III raw material G3 and a Croup V raw material G4 are separately fed.

Discharge ports 31A to 34A of the first to fourth feed passages 31 to 34, respectively, of the raw material feed apparatus 3 are opened at one end 21A of the reaction apparatus 21. The carrier gas G1 and the raw materials G2, G3, G4 and G5 are fed to the main body 21 in a mutually separated state. The carrier gas and the raw materials fed from the discharge ports 31A to 34A to the reaction apparatus 21 flow along the arrow A direction in the reaction apparatus 21, and are discharged from an outlet edge (not shown) provided at other end of the reaction apparatus 21 through the surface of the substrate S (upper face of the substrate S in FIG. 1). The discharged gas is generally treated in an apparatus for treating discharge gas.

As shown in FIG. 1, the reaction apparatus 21 has a structure such that the diameter of the one end 21A is large, the diameter is decreased toward the part to which the substrate S is set, and the discharge ports 31A to 34A are opened toward the substrate S. The carrier gas G1 is discharged from the first feed passage 31 located uppermost. The raw materials are discharged from the second to fourth feed passages 32 to 34 located lower the first feed passage 31. Therefore, the raw materials G2, G3 and G4 are sprayed to the surface of the substrate S by action of the carrier gas G1.

A water cooling mechanism 4 for cooling raw materials flown toward the substrate S is provided at the upstream side of the raw materials flown to the arrow A direction, relative to the position of the susceptor 22. The water cooling mechanism 4 comprises a cooler main body 41 made of molybdenum (Mo) and a protective plate 42 made of boron nitride (BN) on the cooler main body 41.

The raw materials fed to the reaction apparatus 21 from the one end 21A of the reaction apparatus 21 are cooled by the water cooling mechanism 4 during the period until reaching the substrate S. Therefore, the raw materials are effectively prevented from being decomposed until reaching the substrate S. Furthermore, a side reaction between hydrogen halide and ammonia is suppressed.

The protective plate 42 is provided on the cooler main body 41. Therefore, when the raw materials pass through the water cooling mechanism 4, the raw materials are cooled while effectively preventing the raw materials from being contaminated with impurities originating from constituent materials of the cooler main body 41, and additionally, a side reaction between hydrogen halide and a metal is suppressed.

When the Group III-V compound semiconductor is epitaxially grown on the substrate S by a metalorganic chloride method using the semiconductor production apparatus 1, HCl gas is fed to the raw materials. In the semiconductor production apparatus 1, the HCl gas is fed to the second feed passage 32, the third feed passage 33 or the first feed passage 31 which feeds the carrier gas, and the HCl gas is fed to the reaction apparatus 21 together with the Group II raw material or the Group III raw material. In detail, in the semiconductor production apparatus 1, an appropriate amount of HCl gas is fed to the second feed passage 32, the third feed passage 33 or the first feed passage 31 from a cylinder (not shown) filled with HCl gas through a piping (not shown).

Feeding HCl gas to the reaction apparatus 21 by the above-described method suppresses generation of Ga droplets even in the case of increasing the amount of raw materials fed and growing at high growth rate as compared with epitaxial growth by the conventional MOCVD method. For example, in a mirror surface growable region, generation of Ga droplets can effectively be suppressed even at a growth rate (about 15 to 20 μm/hr or more) higher than the conventional MOCVD growth rate (about 5 μm/hr). Furthermore, the epitaxial layer obtained by growth at high rate has sufficiently good crystallinity.

In the case that a light-emitting layer and a functional layer (such as a hole transport layer) are grown on the n-type nitride semiconductor layer thus obtained, the light-emitting layer and the functional layer can be grown without cooling to room temperature in the same reaction furnace after growth of the n-type nitride semiconductor layer. In the case of HVPE, about 2 to 3 hours are required until cooling and taking out the substrate after the growth. However, the production method of the present invention does not require the cooling time.

### Example

### Example 1

A GaN layer having a film thickness of 3 μm was epitaxially grown on C face of a sapphire substrate having a diameter of 50 mm by two-step growth using GaN buffer under the following conditions.

Conditions

Carrier gas: Hydrogen gas (H₂)

Group III element raw material: Trimethyl gallium (TMG)

Group V element raw material: Ammonia

Growth temperature: 1,150° C

TMG feed rate: 0.233 mmol/min

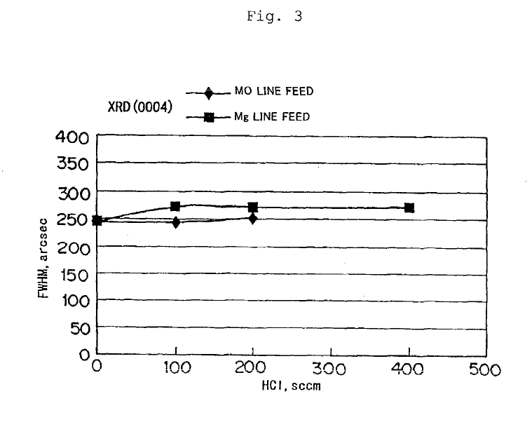

The TMG feed rate was changed to 2.14 mmol/min, HCl gas (HCl 20%/hydrogen 80%) was fed from Mo line or Mg line at 0 to 400 sccm (standard cc/min), and a GaN layer was grown for 30 minutes. Regarding feeding from Mo line and feeding from Mg line, the relationship between the HCl feed rate and the GaN growth rate is shown in FIG. 2. The relationship between the HCl feed rate and X-ray full width at half maximum (FWHM) on (0004) face of the GaN crystal obtained is shown in FIG. 3. The GaN crystal obtained by any of the Mo feed line and the Mg feed line has small FWHM, and its crystallinity was good.

### INDUSTRIAL APPLICABILITY

The production method of the present invention can permit the high rate growth of a Compound III-V compound semiconductor having good crystallinity. The metalorganic vapor phase growth reactor of the present invention is suitably used in the production method of a Group III-V compound semiconductor.

1. A method for producing a Group III-V compound semiconductor, comprising a step of feeding a Group III raw material, a Group V raw material, a carrier gas, and if necessary, other raw materials, to a reactor to grow a Group III-V compound semiconductor on a substrate in the reactor by a metalorganic vapor phase epitaxy, wherein the Group III raw material and the Group V raw material are independently fed to the reactor, and hydrogen halide is fed to the reactor together with a raw material other than the Group V raw material, or the carrier gas.

2. The method of claim 1, wherein the Group V raw material is ammonia.

3. The method of claim 1, wherein the hydrogen halide is hydrogen chloride.

4. A reactor for metalorganic vapor phase growth comprising an inlet for feeding raw materials, a susceptor for placing a substrate for growth thereon, and a water-cooling apparatus for cooling raw materials, wherein the reactor has a cold wall type structure, and the water-cooling apparatus is provided at the upstream side of the susceptor.

5. The reactor of claim 4, wherein the water-cooling apparatus is provided between the inlet and the susceptor.
